(19) United States
(12) Patent Application Publication
(10) Pub. No.: US 2005/0045957 A1
(43) Pub. Date: Mar. 3, 2005

(54) Processing method of silicon controlled rectifier for ESD protection

(76) Inventor: Jung-Cheng Kao, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/923,029

(22) Filed: Aug. 23, 2004

(30) Foreign Application Priority Data
Sep. 1, 2003 (CN) 03150708.5

(51) Int. Cl. H01L 23/62

(52) U.S. Cl. 257/360

(57) ABSTRACT

A processing method of a silicon controlled rectifier (SCR) for ESD protection. In the present invention, a high voltage ion implantation step is utilized to respectively implant the same type ion of comparably high dopant concentration in the first conductive dopant well and in the second conductive dopant well so as to form a first buried dopant area and a second buried dopant area. The silicon controlled rectifier of the present invention can be switch on more quickly and the proper control of the concentration of the buried dopant area is to control the breakdown voltage of the conjunction so as to control of the trigger voltage of the ESD.

### BACKGROUND OF THE INVENTION

1. Field of the Invention

The present invention generally relates to a processing method of an ESD protection device, and more particularly relates to a processing method of a silicon controlled rectifier (SCR) for ESD protection in an integrated circuit.

2. Description of the Prior Art

silicon controlled rectifiers are commonly used in a ESD protection device on a integrated circuit. The main characteristic of the silicon controlled rectifier is the voltage holding characteristic. In the voltage holding region, the silicon controlled rectifier can bear a very high current and can simultaneously hold and cross its low potential voltage. Hence, the device like the silicon controlled rectifier in the integrated circuit is very suitable for leading a high current, such as the current caused from the ESD protection device.

The development of the silicon controlled rectifier used for ESD protection device has continued for more than ten years. The base structure is as shown in FIG. 1a and the description of the application theorem is as shown in the FIG. 1b. As ESD occurs in the pad of an input end, the transverse silicon controlled rectifier will be triggered and go into the snapback region, such as shown in the FIG. 1c. In the snapback region, the transverse silicon controlled rectifier will hold and cross its low potential voltage and maintain a high current. Hence, the ESD current can be effectively led out the current of the ESD.

In deep sub-micron devices of the advanced integrated circuit, the silicon controlled rectifier is suitable for the ESD protection device and the device structure is as shown in the FIG. 2. An N type well 12 and a P type well 14 are formed in the semiconductor substrate 10. In the N type well 12, an N type dopant area 16 and a P type dopant area 18 are respectively formed by using an ion implantation step and also, in the P type well 14, a N type dopant area 20 and a P type dopant area 22 are respectively formed using an ion implantation step. Between the N type well 12 and the P type well 14, there is a shallow trench isolation structure 24 to isolate so as to let the N type dopant area 16 and the P type dopant area 18 of the N type well area 12 to be used as the anode of the silicon controlled rectifier and to let the N type dopant area 20 and the P type dopant area 22 of the P type well area 14 to be used as the ground of the silicon controlled rectifier. This structure of the device is utilized as the ESD protection device.

However, because the breakdown voltage of the conjunction between the N type well and the P type well is not easily controlled, this silicon controlled rectifier for the ESD protection device can not effectively control the trigger voltage of the silicon controlled rectifier. When ESD occurs on the device, this silicon controlled rectifier can not effectively lead out the current of the ESD and thereby loses the effect of ESD protection. Additionally, this silicon controlled rectifier is easily triggered by the noise signal current of the circuit system, so it will cause the latch-up effect during normal working of the circuit because of the triggering of the noise signal.

In accordance with the problems mentioned above, the present invention provides a processing method of a silicoconontrolled rectifier (SCR) for the ESD protection in the integrated circuit which overcomes the disadvantages of the conventional technology.

### SUMMARY OF THE INVENTION

An object of the present invention is to provide a processing method of a silicon controlled rectifier (SCR) for ESD protection, which utilizes a high voltage ion implantation step to form the buried dopant area of a respectively heavily dopant concentration so as to properly control the buried dopant area to achieve the control of the trigger voltage of the ESD.

Another object of the present invention is to provide a processing method of a silicon controlled rectifier (SCR) for ESD protection, when ESD occurs on the device, the silicon controlled rectifier of the present invention can be switch on more quickly so as to effectively lead out the current of the ESD.

A further object of the present invention is to provide a processing method of a silicon controlled rectifier ( SCR) for ESD protection, which can prevent the noise signal current of the circuit system from triggering the formed silicon controlled rectifier so as to effectively prevent the latch-up effect curing normal operation of the circuit.

In order to achieve the previous objects, the present invention provides a semiconductor substrate with an isolation structure on the semiconductor substrate defined as an active area. Then, a first conductive dopant well and a second conductive dopant well are formed within the active area in the semiconductor substrate. Next, a high voltage ion implantation step is utilized to respectively form a first buried dopant area and a second buried dopant area in the first conductive dopant well and the second conductive dopant well, wherein the first buried dopant area and a second buried dopant area are the same type dopant and comparative high dopant concentration. Last, an N type ion dopant area and a P type ion dopant area are formed in the first conductive dopant well and a N type ion dopant area and a P type ion dopant area are also formed in the second conductive dopant well.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1a is the schematic representation of the structure of the base circuit of the silicon controlled rectifier ( SCR) in accordance with prior technology;

FIG. 1b is the schematic representation of the description of the application theorem of the silicon controlled rectifier ( SCR) in accordance with prior technology;

FIG. 1c is the s diagram of curves of the device as the ESD effect occurs;

FIG. 2 is the schematic representation of the structure of the silicon controlled rectifier ( SCR) applied to the ESD protection device; and

FIG. 3a, FIG. 3b, and FIG. 3c are schematic representations of the cross section of the formulation of the silicon controlled rectifier (SCR) in accordance the present invention.

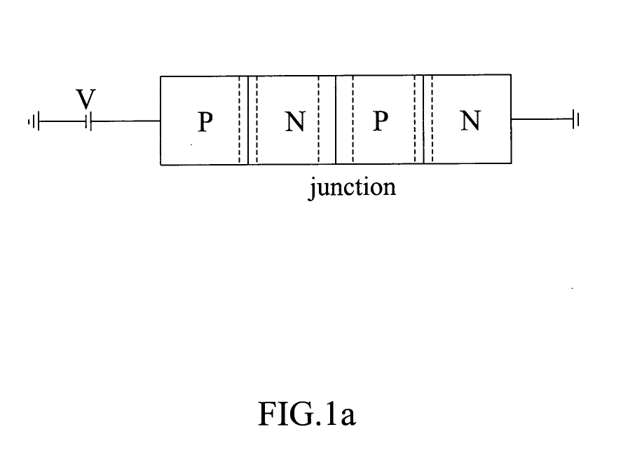

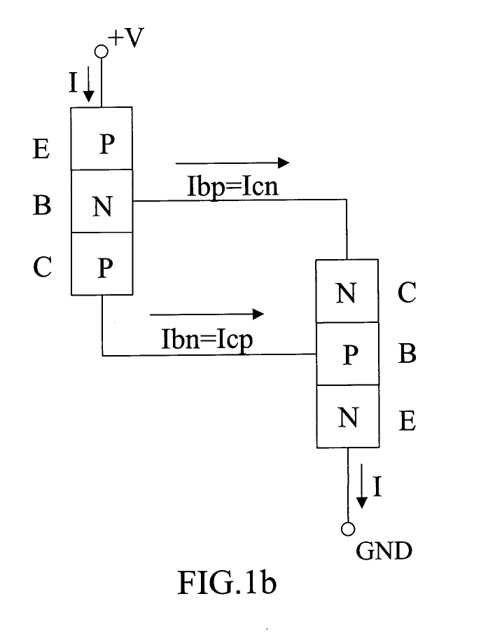

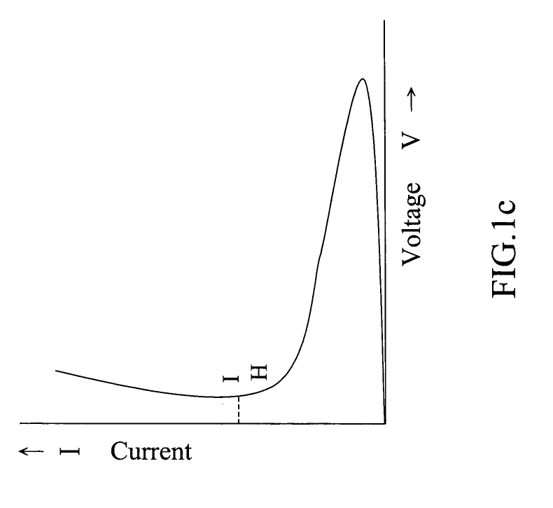

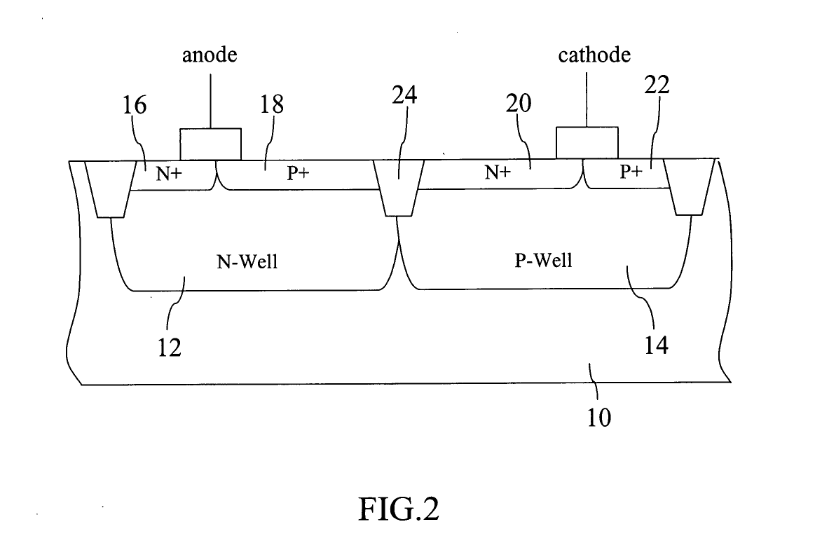

### DESCRIPTION OF THE PREFERRED EMBODIMENT

The present invention provides a processing method of a silicon controlled rectifier ( SCR) for ESD protection, which utilizes a high voltage ion implantation step to form the buried dopant area of a respectively heavily dopant concentration so as to use the proper control of the buried dopant area to achieve the control of the trigger voltage of the ESD.

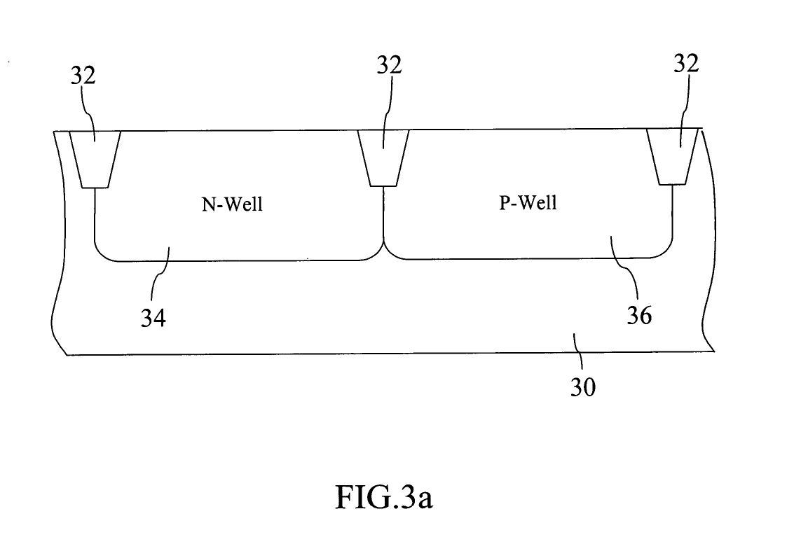

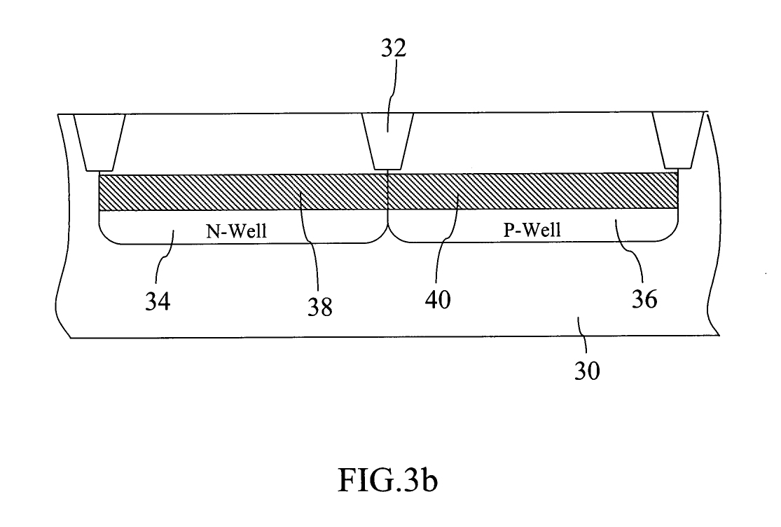

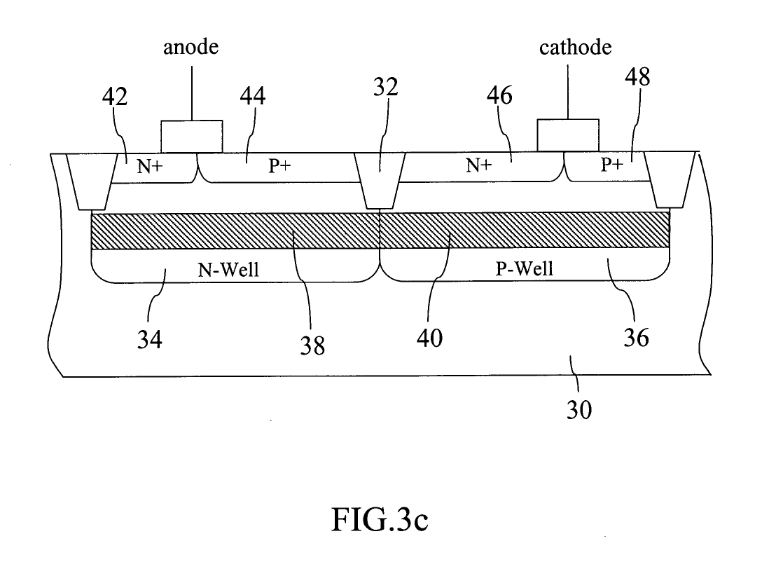

FIG. 3a, FIG. 3b, and FIG. 3c are schematic representations of the cross section of the formulation of the silicon controlled rectifier (SCR) in accordance with an embodiment of the present invention, which takes the PNPN type silicon controlled rectifier for an example to explain the fabricating procedures of the present invention.

Referring to FIG. 3a, first, a semiconductor substrate 30 is provided and there are plurality of shallow trench isolation structures 32 formed on the semiconductor substrate 30 to define an active area. Then, performing an N+ ion implantation step within the active area in the semiconductor substrate 30, an N type dopant area 34 is formed in the semiconductor substrate 30, wherein the N type dopant area 34 is the first conductive dopant well. Next, performing an P+ ion implantation step, a P type dopant area 36 is formed in the semiconductor substrate 30, wherein the P type dopant area 36 is the second conductive dopant well. The N type dopant area 34 and the P type dopant area 36 are adjacent to form a conjunction. The position between the N type dopant area 34 and the P type dopant area 36 and near the surface of the semiconductor substrate 30, the shallow trench isolation structure 32 is used to isolate the N type dopant area 34 and the P type dopant area 36.

Following, referring to FIG. 3b, a high voltage ion implantation step, such as a retrograde ion implantation step, is utilized to respectively perform a heavily N+ ion implantation step and a P+ ion implantation step in the N type dopant well 34 and the P type dopant well 36 by utilizing a high energy over 200 KeV to implant the N⁺ ion and P+ ion with a concentration over 1*10¹³ per cm² into the semiconductor substrate 3 so as to form a buried N+ dopant area 38 of a comparative high dopant concentration in the N type dopant well 34 and to form a buried P+ dopant area 40 of a comparative high dopant concentration in the P type dopant well 36.

Last, referring to FIG. 3c, the ion implantation step is performed in the N type dopant well 34 to form a N type ion dopant area 42 and a P type ion dopant area 44, and simultaneously, the ion implantation step is performed in the P type dopant well 36 to form a N type ion dopant area 46 and a P type ion dopant area 48, wherein the P type ion dopant area 44 and the N type ion dopant area 46 are separated by the shallow trench isolation structure 32. The N type ion dopant area 42 and the P type ion dopant area 44 of the N type well area 34 are used as the anode of the silicon controlled rectifier and lets the N type ion dopant area 46 and the P type ion dopant area 48 of the P type well area 36 to be used as the ground of the silicon controlled rectifier.

To sum up the forging, the present invention forms the buried N+ dopant area 38 and the buried P+ dopant area 40 with the comparative high dopant concentration in the N type well area 34 and the P type dopant well 36 in the semiconductor substrate 30, so as the transverse silicon controlled rectifier of the present invention can be switch on more quickly and successively control the ion concentration of the buried dopant areas 38, 40 to control the breakdown voltage of the conjunction between the N+ and the P+ so as to achieve the control of the trigger voltage of the transverse silicon controlled rectifier for the ESD protection device.

Furthermore, the present invention utilizes the control of the ion concentration of the buried dopant areas to maintain the trigger voltage of the ESD. Hence, as the ESD occurs on the device, the silicon controlled rectifier of the present invention can be switched on more quickly so as to effectively lead out the current of the ESD. Additionally, the present invention can prevent the noise signal current of the circuit system from triggering the formed silicon controlled rectifier so as to effectively prevent the latch-up effect during normal operation of the circuit.

The forgoing description of the embodiments of the invention has been presented for purposes of illustration and description, and is not intended to be exhaustive or to limit the present invention to he precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

1. A processing method of a silicon controlled rectifier for ESD protection comprising:
providing a semiconductor substrate, wherein an isolation structure thereon is formed to define an active area;
forming a first conductive dopant well and a second conductive dopant well within the active area on the semiconductor substrate;
utilizing a high voltage ion implantation step to respectively form a first buried dopant area and a second buried dopant area in the first conductive dopant well and the second conductive dopant well, wherein the first buried dopant area and the second buried dopant area are the same type dopant and comparative high dopant concentration; and
forming an N type ion dopant area and a P type ion dopant area in the first conductive dopant well and also forming an N type ion dopant area and a P type ion dopant area in the second conductive dopant well.

2. The processing method of a silicon controlled rectifier for ESD protection according to claim 1, wherein the isolation structure is a shallow trench isolation structure.

3. The processing method of a silicon controlled rectifier for ESD protection according to claim 1, wherein the first conductive dopant well is a N type dopant well and the first buried dopant area is a buried N dopant area.

4. The processing method of a silicon controlled rectifier for ESD protection according to claim 3, wherein the first buried dopant area is formed by utilizing a high energy over 200 KeV to implant the N⁺ ion with a concentration over 1*10¹³ per cm² into the first conductive dopant area.

5. The processing method of a silicon controlled rectifier for ESD protection according to claim 1, wherein the second conductive dopant well is the P type dopant well and the second buried dopant area is the buried P dopant area.

6. The processing method of a silicon controlled rectifier for ESD protection according to claim 5, wherein the second buried dopant area is formed by utilizing a high energy over 200 KeV to implant the P⁺ ion with a concentration over 1*10¹³ per cm² into the second conductive dopant area

7. The processing method of a silicon controlled rectifier for ESD protection according to claim 1, wherein the high voltage ion implantation step utilizes an retrograde ion implantation step to form the first buried dopant area and the second buried dopant area.
